(19) United States
(12) Patent Application Publication
(10) Pub. No.: US 2025/0228115 A1
(43) Pub. Date: Jul. 10, 2025

(54) DISPLAY DEVICE AND METHOD OF MANUFACTURING DISPLAY DEVICE

(71) Applicant: Sharp Display Technology Corporation, Kameyama City (JP)

(72) Inventors: Kenichi OHGURI, Kameyama City (JP); Katsuhiro YAMAGUCHI, Kameyama City (JP); Takayuki YAMADA, Kameyama City (JP); Yuhji TANIGUCHI, Kameyama City (JP); Hiroshi OGITA, Kameyama City (JP); Yasukazu TOMITA, Kameyama City (JP); Motoji SHIOTA, Kameyama City (JP); Hiroki KAWAMURA, Kameyama City (JP); Kazuki NAKASHIMA, Kameyama City (JP)

(21) Appl. No.: 19/001,760

(22) Filed: Dec. 26, 2024

(30) Foreign Application Priority Data
Jan. 9, 2024 (JP) 2024-001168

(51) Int. Cl. H10K 59/80; H10K 59/18; H10K 102/00

(52) U.S. Cl. CPC H10K 59/8794; H10K 59/18; H10K 2102/311

(57) ABSTRACT

A display device includes a display unit having flexibility and including a first film, a first display panel, a second film, a second display panel, and a heat dissipation part. The first film and the second film are bonded together around the first display panel and the second display panel.

### CROSS-REFERENCE TO RELATED APPLICATIONS

This application claims the benefit of priority to Japanese Patent Application Number 2024-001168 filed on Jan. 9, 2024. The entire contents of the above-identified application are hereby incorporated by reference.

### BACKGROUND

### Technical Field

The disclosure relates to a display device having flexibility and a method of manufacturing the display device.

A foldable display device is disclosed in JP 2022-536882 A.

### SUMMARY

In a foldable display device as disclosed in JP 2022-536882 A, the bending of the display unit may result in a decrease in durability or reliability of the display device or a decrease in the display quality of the display device. This becomes more noticeable in a display device that includes a plurality of display panels and has display surfaces on both sides.

A display device according to one aspect of the disclosure is a display device including a display unit having flexibility, in which the display unit includes a first film, a second film overlapping the first film in a plan view, a first display panel positioned between the first film and the second film and including a display surface on a side of the first film, a second display panel positioned between the second film and the first display panel and including a display surface on a side of the second film, and a heat dissipation part positioned between the first display panel and the second display panel and having a thermal conductivity higher than a thermal conductivity of at least one of the first display panel and the second display panel, and the first film and the second film are bonded together around the first display panel and the second display panel in a plan view.

A method of manufacturing a display device according to an aspect of the disclosure is a method of manufacturing a display device including a display unit having flexibility, the method including forming the display unit, in which formation of the display unit includes forming a layered body including a first film, a second film overlapping the first film in a plan view, a first display panel positioned between the first film and the second film and including a display surface on a side of the first film, a second display panel positioned between the second film and the first display panel and including a display surface on a side of the second film, and a heat dissipation part positioned between the first display panel and the second display panel and having a thermal conductivity higher than a thermal conductivity of at least one of the first display panel and the second display panel, and bonding the first film and the second film together around the first display panel and the second display panel in a plan view.

In a display device having display surfaces on both sides and having flexibility, durability and reliability are improved, or display quality on each display surface is improved.

### BRIEF DESCRIPTION OF DRAWINGS

The disclosure will be described with reference to the accompanying drawings, wherein like numbers reference like elements.

FIG. 1 is a schematic exploded view of a display device according to a first embodiment.

FIG. 2 is a schematic perspective view of the display device according to the first embodiment.

FIG. 3 is a schematic side cross-sectional view of a portion of the display device according to the first embodiment.

FIG. 4 is a flowchart of a method of manufacturing the display device according to the first embodiment.

FIG. 5 is a perspective view illustrating steps of the method of manufacturing the display device according to the first embodiment.

FIG. 6 is a perspective view illustrating other steps of the method of manufacturing the display device according to the first embodiment.

FIG. 7 is a schematic exploded view of a display device according to a second embodiment.

FIG. 8 is a schematic side cross-sectional view of a portion of the display device according to the second embodiment.

FIG. 9 is a schematic perspective view of a display device according to a third embodiment.

FIG. 10 is a schematic exploded view of the display device according to the third embodiment.

FIG. 11 is a schematic view of each bonding plate according to the third embodiment.

FIG. 12 is a schematic side cross-sectional view of a portion of the display device according to the third embodiment.

FIG. 13 is a flowchart of a method of manufacturing the display device according to the third embodiment.

FIG. 14 is a perspective view illustrating steps of the method of manufacturing the display device according to the third embodiment.

FIG. 15 is a perspective view illustrating other steps of the method of manufacturing the display device according to the third embodiment.

FIG. 16 is a schematic view illustrating a fusing position of each bonding plate in the method of manufacturing the display device according to the third embodiment.

### DESCRIPTION OF EMBODIMENTS

### First Embodiment

Hereinafter, embodiments of the disclosure will be described in detail. The drawings in this disclosure are merely illustrative and do not illustrate the actual scale of respective members. Furthermore, for simplicity of illustration, members having the same configuration in each drawing in this disclosure are given the same reference numeral, while the scale may differ between the drawings and hatching may be different. Members having the same functions as the members previously described in each embodiment of this disclosure are given the same reference numerals, and their descriptions will not be repeated.

### Display Device: Overview

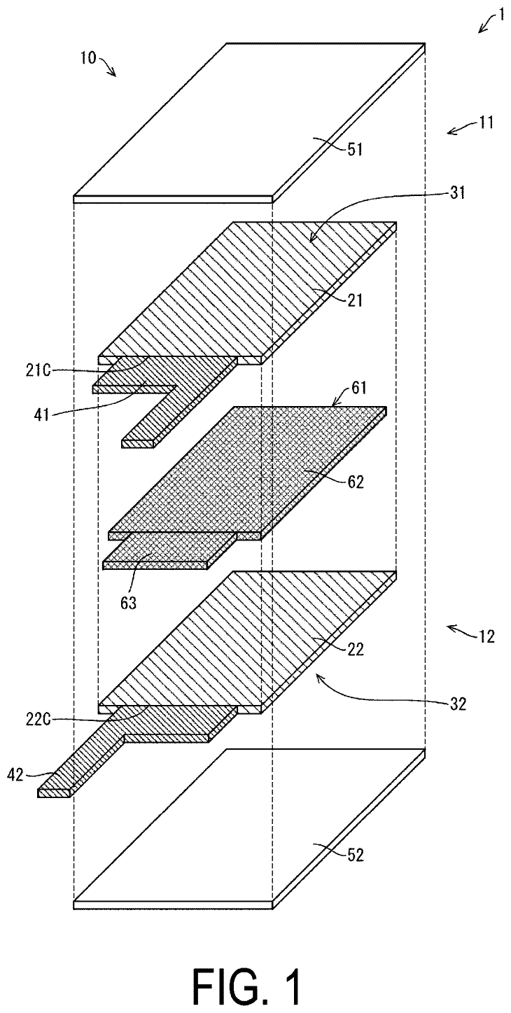

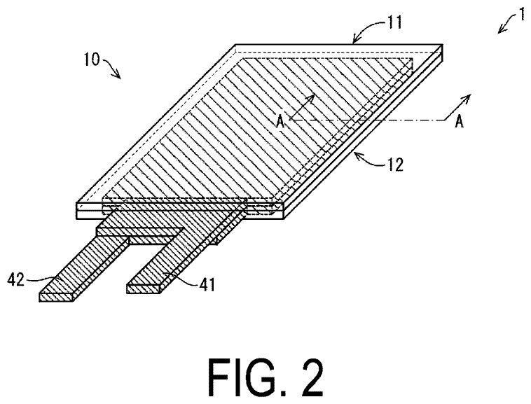

FIG. 2 is a schematic perspective view of a display device 1 according to this embodiment. FIG. 1 is a schematic exploded view of the display device 1 according to this embodiment, and particularly, is a diagram illustrating parts of the display device 1 exploded in a direction substantially the same as the up-down direction of the display device 1. Two points connected by a dotted line in FIG. 1 indicate overlapping positions in a plan view of the display device 1. In the perspective views of the respective display devices in this disclosure, including FIGS. 1 and 2, description will be given on the assumption that the upper side on the paper surface faces an upward direction, and the lower side faces a downward direction.

As illustrated in FIGS. 1 and 2, the display device 1 includes a display unit 10. The display unit 10 according to this embodiment is flexible and can be bent, for example, in an in-plane direction of the display unit 10, with the upper surface side of the display unit 10 as at least one of the peak side and valley side.

### Display Device: Display Panel

The display unit 10 includes a first part 11 and a second part 12 layered on each other. In particular, as illustrated in FIG. 1, the display unit 10 includes a first display panel 21 as a part of the first part 11, and includes a second display panel 22 as a part of the second part 12. A first display panel 21 and a second display panel 22 may overlap each other in a plan view of the display unit 10. The first display panel 21 has a first display surface 31 on the upper surface side of the display unit 10, and the second display panel 22 has a second display surface 32 on the lower surface side of the display unit 10.

The first display panel 21 and the second display panel 22 may be, for example, light-emitting panels including a plurality of light-emitting elements in an in-plane direction. In particular, at least one of the first display panel 21 and the second display panel 22 may be an organic EL light-emitting panel including a plurality of organic EL elements arranged in an in-plane direction. Alternatively, at least one of the first display panel 21 and the second display panel 22 may be a quantum dot light-emitting panel including a plurality of quantum dot light-emitting elements arranged in an in-plane direction.

### Display Device: Circuit Board

Here, the display device 1 may include a first circuit board 41 connected to a side of the first display panel 21 and a second circuit board 42 connected to a side of the second display panel. The first circuit board 41 and the second circuit board 42 may be, for example, flexible printed circuit boards. The first circuit board 41 and the second circuit board 42 may be circuits for transmitting drive signals from a display control unit of the display device 1 to each light-emitting element of the first display panel 21 and each light-emitting element of the second display panel 22 via a driver (not illustrated). In this manner, the first circuit board 41 and the second circuit board 42 make it possible to input a signal for driving the display of each of the first display panel 21 and the second display panel 22 from the outside of the display device 1 to each display panel.

In addition, each of the first display panel 21 and the second display panel 22 may have a rectangular shape having four sides in a plan view. In this case, the first display panel 21 may have a first side 21C which is one of the four sides, and the second display panel 22 may have a second side 22C which is one of the four sides. The second side 22C may be positioned on the same side as the first side 21C in a plan view.

Here, the first circuit board 41 and the second circuit board 42 may overlap in a plan view. In particular, the first circuit board 41 may be connected to the side of the first side 21C of the first display panel 21, and the second circuit board 42 may be connected to the side of the second side 22C of the second display panel 22. In this case, the position of the first circuit board 41 and the position of the second circuit board 42 overlap each other in a plan view, and the shape of the periphery of the first display panel 21 and the second display panel 22 in a plan view of the display device 1 is simplified.

### Display Device: Film

Furthermore, as illustrated in FIG. 1, the display unit 10 includes a first film 51 as a part of the first part 11, and a second film 52 as a part of the second part 12. The second film 52 overlaps with the first film 51 in a plan view of the display unit 10. The first film 51 is positioned on the side of the first display surface 31 of the first display panel 21, and the second film 52 is positioned on the side of the second display surface 32 of the second display panel 22.

For this reason, the first display panel 21 and the second display panel 22 are positioned between the first film 51 and the second film 52. The first display panel 21 has a first display surface 31 as a display surface on the side of the first film 51, and the second display panel 22 has a second display surface 32 as a display surface on the side of the second film 52.

The first film 51 and the second film 52 are transparent films that transmit at least light emitted by the first display panel 21 and the second display panel 22. In other words, the first display panel 21 and the second display panel 22 perform display on the first display surface 31 and the second display surface 32, respectively, through the first film 51 and the second film 52.

At least one of the first film 51 and the second film 52 may include a polarizing film. In this case, the display device 1 can reduce external light reflection on at least one of the first display surface 31 and the second display surface 32. Thereby, the display device 1 improves display quality with a simple configuration. The display unit 10 may include a flexible wave plate between the first display panel 21 and the first film 51 or between the second display panel 22 and the second film 52. At least one of the first film 51 and the second film 52 may include polyimide. In this case, in the display device 1, both light-transmitting property and flexibility in at least one of the first film 51 and the second film 52 are improved.

As will be described later in detail, the first film 51 and the second film 52 are bonded together around the first display panel 21 and the second display panel 22 in a plan view of the display device 1. For example, the first film 51 and the second film 52 are bonded together around each part of the end edge of the display unit 10 of the display device 1 in a plan view, excluding parts that are connected to the first circuit board 41 and the second circuit board 42.

### Display Device: Heat Dissipation Plate

In addition, as illustrated in FIG. 1, the display unit 10 includes a heat dissipation plate 61 as a heat dissipation part that is, for example, a part of the second part 12. The heat dissipation plate 61 has a flat plate shape and is positioned between the first display panel 21 and the second display panel 22. The heat dissipation plate 61 has a thermal conductivity higher than that of at least one of the first display panel 21 and the second display panel 22. For example, the heat dissipation plate 61 may include a material that has a thermal conductivity higher than that of a material included in at least one of the first display panel 21 and the second display panel 22.

The heat dissipation plate 61 may be formed on the upper surface of the second display panel 22 and the upper surface of the second circuit board 42. However, without being limited thereto, the heat dissipation plate 61 may be formed on the lower surface of the first display panel 21 and the lower surface of the first circuit board 41, in which case the display unit 10 may include the heat dissipation plate 61 as a part of the first part 11.

The heat dissipation plate 61 may propagate heat generated from at least one of the first display panel 21 and the second display panel 22 to the outside of the display device 1 and may also discharge the heat to the outside of the display device 1. In this manner, the heat dissipation plate 61 reduces deterioration due to heat generation from at least one of the first display panel 21 and the second display panel 22, and extends the life of the display device 1. In particular, the display device 1 extends the life of the heat dissipation plate 61 having a flat plate shape with a simple configuration by disposing the heat dissipation plate 61 between the first display panel 21 and the second display panel 22.

In general, in organic EL elements and quantum dot light-emitting elements, a light-emitting material may deteriorate due to heat, resulting in a decrease in light-emitting efficiency. For this reason, when at least one of the first display panel 21 and the second display panel 22 is an organic EL light-emitting panel or a quantum dot light-emitting panel, the display device 1 efficiently reduces the deterioration of each light-emitting element and extends its life.

The heat dissipation plate 61 includes a display panel heat dissipation plate 62 overlapping at least one of the first display panel 21 and the second display panel 22, and a circuit board heat dissipation plate 63 overlapping at least one of the first circuit board 41 and the second circuit board 42 in a plan view of the display unit 10. In particular, the circuit board heat dissipation plate 63 may overlap, in a plan view, a portion where the first circuit board 41 and the second circuit board 42 overlap each other in a plan view. In this case, the heat dissipation plate 61 may discharge heat generated from the first circuit board 41 and the second circuit board 42 to the outside of the display device 1. Thereby, the heat dissipation plate 61 may reduce deterioration due to heat generation from the first circuit board 41 and the second circuit board 42, and further extend the life of the display device 1.

### Resin Bonding Material

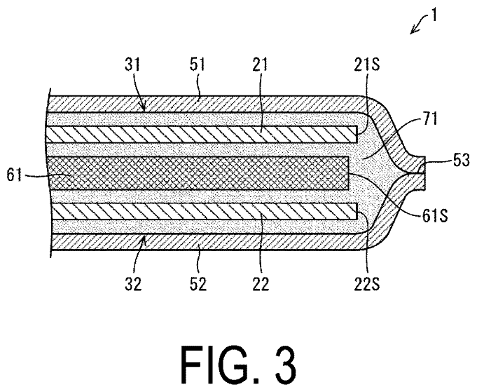

The bonding of each part of the display unit 10 may be performed particularly using a bonding material including a resin material having light-transmitting property. The bonding material according to this embodiment will be described with reference to FIG. 3. FIG. 3 is a schematic side cross-sectional view of a part of the display device 1 according to this embodiment. In particular, FIG. 3 is a cross-sectional view taken along a line A-A illustrated in FIG. 2, in other words, illustrates a side cross-section substantially parallel to the layering direction of the display unit 10 in the vicinity of the end edge of the display unit 10 of the display device 1 in a plan view. The end edge through which the side cross-section illustrated in FIG. 3 passes is different from the end edge on which the first circuit board 41 and the second circuit board 42 are formed.

As illustrated in FIG. 3, the display device 1 may include a resin bonding material 71. The resin bonding material 71 includes a resin material having light-transmitting property. The resin bonding material 71 is positioned between the first film 51 and the first display panel 21, between the first display panel 21 and the heat dissipation plate 61, between the heat dissipation plate 61 and the second display panel 22, and between the second display panel 22 and the second film 52. The resin bonding material 71 bonds the members of the display unit 10 described above.

Additionally, the first film 51 and the second film 52, which are positioned on the peripheral side of the display unit 10 in a plan view of the display device 1, are bonded together at a bonding part 53 illustrated in FIG. 3. In particular, the bonding part 53 is formed around each part of the end edge of the display unit 10 of the display device 1 in a plan view, excluding parts that are connected to the first circuit board 41 and the second circuit board 42.

In this case, as illustrated in FIG. 3, the resin bonding material 71 may be filled between the bonding part 53 between the first film 51 and the second film 52 and the sides of the first display panel 21, the second display panel 22, and the heat dissipation plate 61. In particular, as illustrated in FIG. 3, a side surface 21S of the first display panel 21, a side surface 22S of the second display panel 22, and a side surface 61S of the heat dissipation plate 61 may be covered with the resin bonding material 71. The resin bonding material 71 is positioned between the bonding part 53 and the sides ranging from the first display panel 21 to the second display panel 22, and thus the display device 1 can reduce the penetration of moisture and the like into each part of the display unit 10. Furthermore, the resin bonding material 71 has light-transmitting property, and thus the display device 1 can reduce the influence of the resin bonding material 71 on the display in the display unit 10.

### Protection Effect of Display Unit

The display unit 10 of the display device 1 according to this embodiment includes the first display panel 21 having the first display surface 31 and the second display panel 22 having the second display surface 32, between the first film 51 and the second film 52 that overlap each other in a plan view. The display unit 10 also includes the heat dissipation plate 61 between the first display panel 21 and the second display panel 22. Furthermore, the first film 51 and the second film 52 are bonded together around the first display panel 21 and the second display panel 22 in a plan view.

Thereby, the display device 1 can discharge heat generated from at least one of the first display panel 21 and the second display panel 22 to the outside of the display device 1 via the heat dissipation plate 61. Thereby, the display device 1 can reduce deterioration of at least one of the first display panel 21 and the second display panel 22 due to heat generated in the display unit 10.

In particular, the heat dissipation plate 61 includes the circuit board heat dissipation plate 63 between the first circuit board 41 and the second circuit board 42 which are connected to the peripheral side of the display unit 10 in a plan view. Here, the first film 51 and the second film 52 are not bonded together at portions where they overlap the first circuit board 41 and the second circuit board 42 in a plan view. For this reason, heat propagated from the first display panel 21 and the second display panel 22 to the display panel heat dissipation plate 62 is further efficiently discharged to the outside of the display device 1 via the circuit board heat dissipation plate 63. Thus, the heat dissipation plate 61 can more efficiently discharge heat generated between the first display panel 21 and the second display panel 22 to the outside of the display device 1.

Furthermore, the display device 1 can reduce the penetration of foreign matter such as moisture into each display panel by the first film 51 and the second film 52 that are bonded together around each display panel in a plan view. Thereby, the display device 1 reduces deterioration of at least one of the first display panel 21 and the second display panel 22 due to the penetration of foreign matter from the outside of the display device 1. In addition, the first film 51 and the second film 52 alleviate stress that occurs in each display panel as the display unit 10 is bent. Thereby, the display device 1 reduces deterioration of at least one of the first display panel 21 and the second display panel 22 as the display unit 10 of the display device 1 is bent.

Thus, the display device 1 improves the durability and reliability of the display unit 10, which has display surfaces on both the upper and lower surfaces and has flexibility, or improves the display quality of at least one of the first display surface 31 and the second display surface 32.

### Method of Manufacturing Display Device

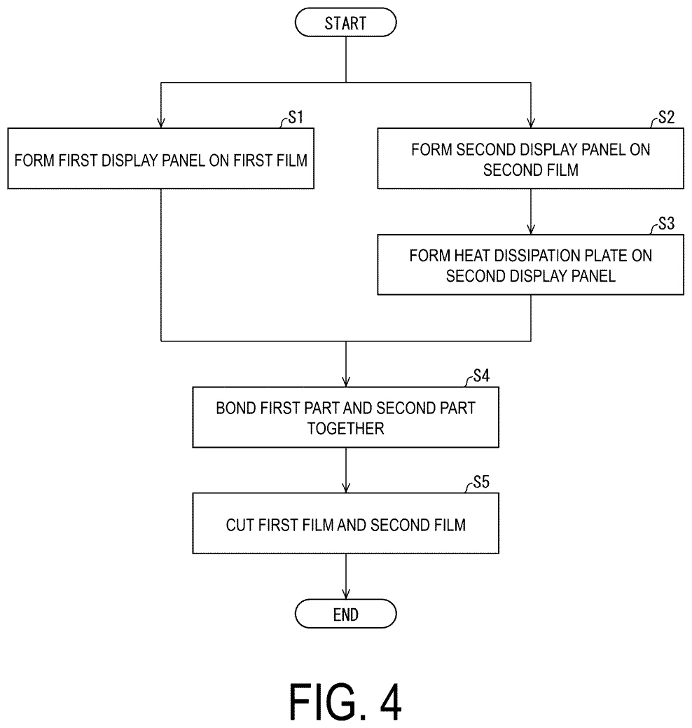

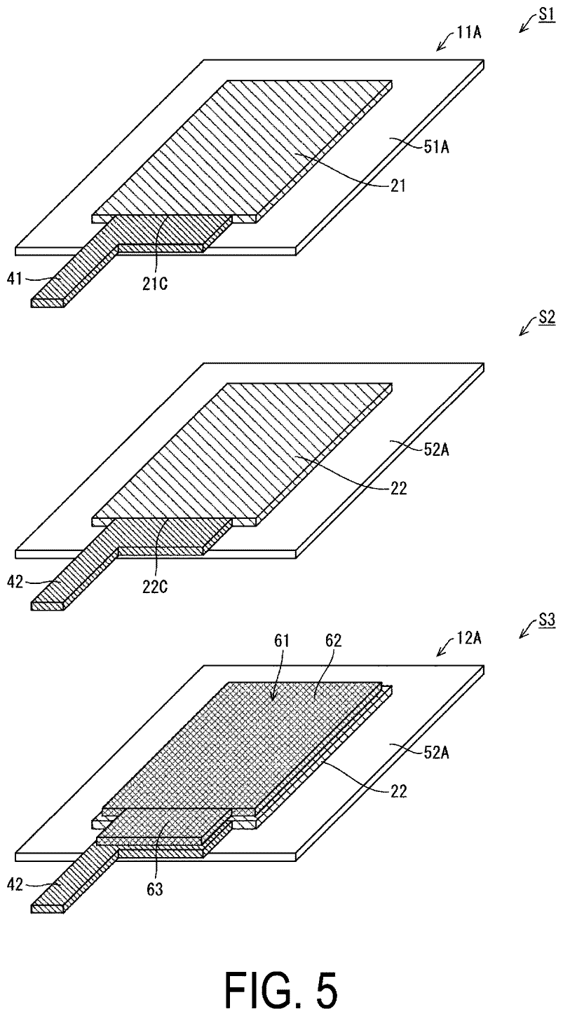

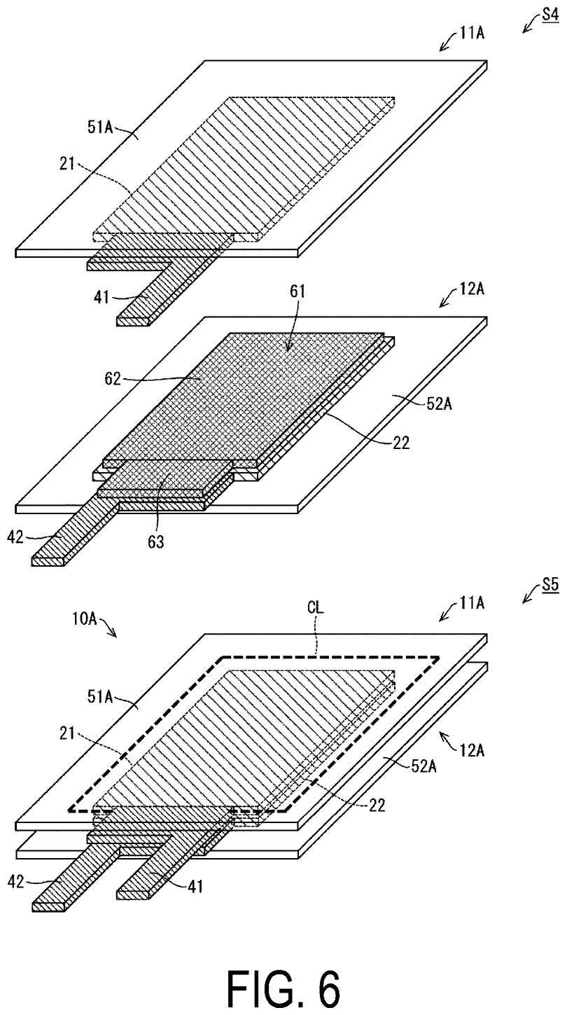

A method of manufacturing the display device 1 according to this embodiment will be described with reference to FIGS. 4 to 6. FIG. 4 is a flowchart of a method of manufacturing the display device 1 according to this embodiment. FIGS. 5 and 6 are perspective views illustrating steps of the method of manufacturing the display device 1 according to this embodiment.

In the method of manufacturing the display device 1 according to this embodiment, first, the first display panel 21 is formed on a first film 51A (step S1). Here, the first film 51A may have a larger dimension in the in-plane direction in a plan view than the first film 51. In step S1, the first display panel 21 is formed to have the first display surface 31 on the side of the first film 51A.

Step S1 may be executed by forming a flexible substrate such as a film substrate on the first film 51A to which the resin bonding material 71 (not illustrated) has been applied, and forming light-emitting elements on the substrate to form the first display panel 21. Alternatively, step S1 may be executed by peeling the first display panel 21, which has been formed on a separate substrate, from the substrate and then bonding it to the first film 51A via the resin bonding material 71. In step S1, the first circuit board 41 to be connected to the first side 21C of the first display panel 21 may be formed.

A first part 11A may be formed by step S1. The first part 11A may have the same configuration as the first part 11 except that the first film 51 is replaced with the first film 51A.

Apart from the formation of the first part 11A, in the method of manufacturing the display device 1 according to this embodiment, as illustrated in FIG. 5, the second display panel 22 is formed on a second film 52A (step S2). Here, the second film 52A may have a larger dimension in the in-plane direction in a plan view than the second film 52, and this dimension may be substantially the same as that of the first film 51A. Step S2 may be executed by the same method as in step S1. In particular, in step S2, the second display panel 22 is formed to have the second display surface 32 on the side of the second film 52A.

Subsequently to step S2, the heat dissipation plate 61 is formed on the second display panel 22 (step S3). Step S3 may be executed by disposing the heat dissipation plate 61 on the second display panel 22 via the resin bonding material 71 (not illustrated). In step S3, the heat dissipation plate 61 may be disposed such that the display panel heat dissipation plate 62 is positioned on the second display panel 22 and the circuit board heat dissipation plate 63 is positioned on the second circuit board 42.

A second part 12A may be formed by step S3. The second part 12A may have the same configuration as the second part 12 except that the second film 52 is replaced with the second film 52A.

Subsequently to steps S1 and S3, the first part 11A and the second part 12A are bonded together (step S4). Step S4 may be performed, for example, by applying the resin bonding material 71 (not illustrated) to at least one of the side of the first display panel 21 of the first part 11A and the side of the heat dissipation plate 61 of the second part 12A, and bonding the first part 11A and the second part 12A together via the resin bonding material 71. In step S4, the first film 51A and the second film 52A may be bonded together via the resin bonding material 71. As described above, a layered body 10A is formed such that the second film 52A, the second display panel 22, the heat dissipation plate 61, the first display panel 21, and the first film 51 are layered in this order.

Next, the first film 51A and the second film 52A are cut (step S5). For example, in step S5, as illustrated in FIG. 6, the first film 51A and the second film 52A may be cut along a cutting line CL positioned on the periphery side of each display panel in a plan view in the first film 51A and the second film 52A. The cutting line CL may be formed along the end edge of each display panel at a position on the periphery of each display panel in a plan view, excluding the portions overlapping the first circuit board 41 and the second circuit board 42.

The cutting of the first film 51A and the second film 52A in step S5 may be performed by fusing the first film 51A and the second film 52A using a laser beam or the like. In this case, the first film 51A and the second film 52A may be bonded together by dissolving them by fusing and bringing them into contact with each other, and then solidifying them again. When the first film 51A and the second film 52A are bonded together via the resin bonding material 71, the resin bonding material 71 may be filled between a bonding part between the first film 51A and the second film 52A and the sides of each display panel and the heat dissipation plate 61.

In step S5, the first film 51A and the second film 52A are cut into the first film 51 and the second film 52, respectively, and the first film 51 and the second film 52 are bonded together at the bonding part 53. By bonding the first film 51 and the second film 52 together while cutting the first film 51A and the second film 52A, it is not necessary to bond the first film 51A and the second film 52A separately, and the method of manufacturing the display device 1 is further simplified. However, this is not limiting, and the first film 51A and the second film 52A may be bonded separately by heating the first film 51A and the second film 52A or by applying ultrasonic vibration to the first film 51A and the second film 52A.

As described above, the layered body 10A becomes the display unit 10, and the display device 1 is manufactured. As described above, the display device 1 manufactured by the above-described method improves the durability and reliability of the display unit 10 or improves the display quality of at least one of the first display surface 31 and the second display surface 32.

### Second Embodiment

### Heat Dissipation Bonding Part

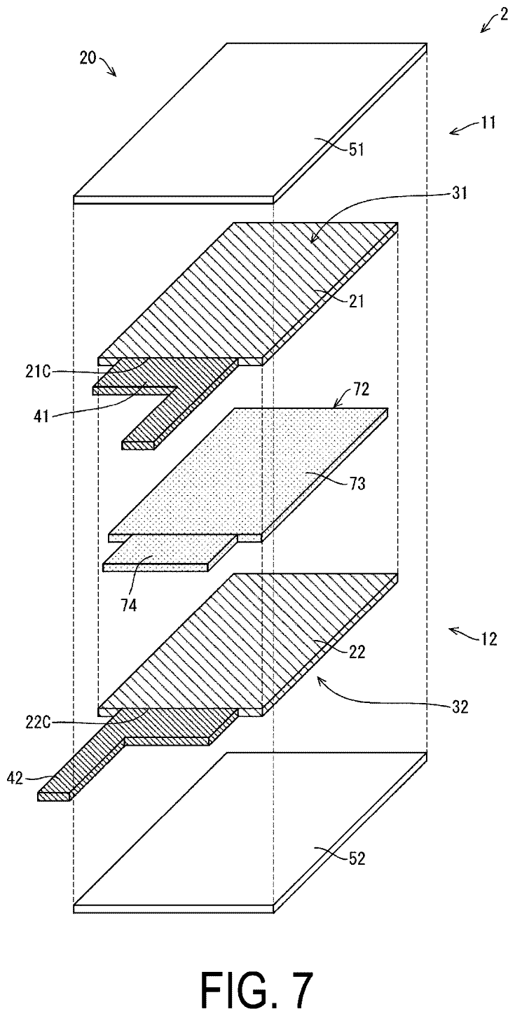

FIG. 7 is a schematic exploded view of a display device 2 according to this embodiment. The display device 2 according to this embodiment differs in configuration from the display device 1 according to the previous embodiment in that it includes a display unit 20 instead of the display unit 10. The display unit 20 according to this embodiment differs in configuration from the display unit 10 according to the previous embodiment only in that it includes a heat dissipation bonding part 72 as a heat dissipation part instead of a heat dissipation plate 61.

The heat dissipation bonding part 72 is positioned between a first display panel 21 and a second display panel 22, and has a thermal conductivity higher than that of at least one of the first display panel 21 and the second display panel 22. For example, the heat dissipation bonding part 72 may be formed by mixing a material such as a filler with a high thermal conductivity into a bonding material such as OCA.

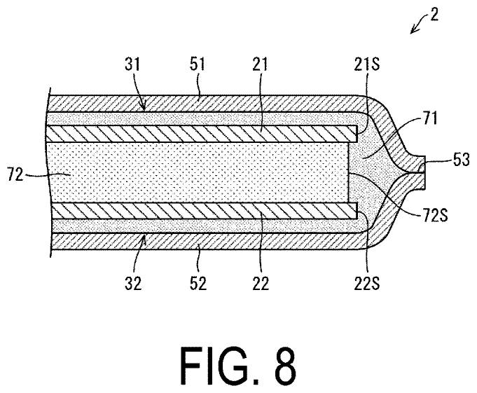

FIG. 8 is a schematic side cross-sectional view of a portion of the display device 2 according to this embodiment, and particularly, is a schematic side cross-sectional view of a portion of the display device 2 at a position corresponding to the schematic side cross-section illustrated in FIG. 3. As illustrated in FIG. 8, the heat dissipation bonding part 72 bonds the first display panel 21 and the second display panel 22 together. In other words, the first display panel 21 and the second display panel 22 are bonded together via the heat dissipation bonding part 72.

Bonding between the first display panel 21 and a first film 51 and bonding of the second display panel 22 and a second film 52 may be performed using a resin bonding material 71. In this case, the resin bonding material 71 may be filled between a bonding part 53 and sides ranging from the first display panel 21 to the second display panel 22. In other words, a side surface 72S of the heat dissipation bonding part 72 may be covered with the resin bonding material 71.

Returning back to FIG. 7, the heat dissipation bonding part 72 includes a display panel bonding part 73 and a circuit board bonding part 74. The display panel bonding part 73 overlaps at least one of the first display panel 21 and the second display panel 22 in a plan view of the display unit 20, and bonds the first display panel 21 and the second display panel 22 together. The circuit board bonding part 74 overlaps at least one of a first circuit board 41 and a second circuit board 42 in a plan view of the display unit 20 and bonds the first circuit board 41 and the second circuit board 42 together.

The heat dissipation bonding part 72 may propagate heat generated from at least one of the first display panel 21 and the second display panel 22 to the outside of the display device 2 and may also discharge the heat to the outside of the display device 2. In particular, the heat dissipation bonding part 72 discharges the heat to the outside of the display device 2 via the display panel bonding part 73 and the circuit board bonding part 74 in that order. Thus, the display device 2 can cause the heat dissipation bonding part 72 to have both a function of bonding the first display panel 21 and the second display panel 22 together and a function of discharging heat in the display unit 20. Thus, the display device 2 extends its life with a simpler configuration.

Except for the above description, the display device 2 has the same configuration as the display device 1 described above. Thus, for the same reasons as those described above, the display device 2 improves the durability and reliability of the display unit 20 or improves the display quality of at least one of a first display surface 31 and a second display surface 32.

The display device 2 according to this embodiment may be manufactured by a method with some modifications of the method of manufacturing the display device 1 described above. For example, in step S3 of this embodiment, the heat dissipation bonding part 72 may be formed on the second display panel 22 instead of the heat dissipation plate 61. In addition, in step S4 of this embodiment, a first part 11A and a second part 12A may be bonded together via the heat dissipation bonding part 72.

### Third Embodiment

### First and Second Bonding Plates

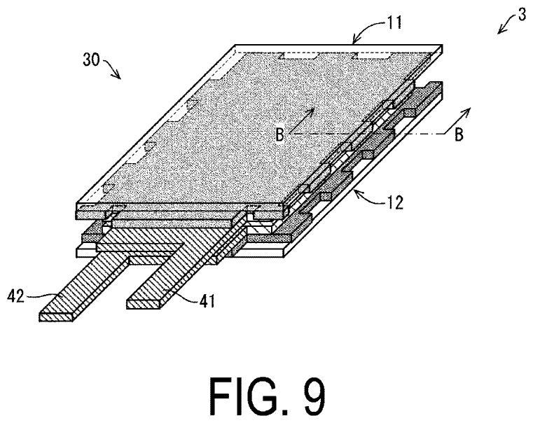

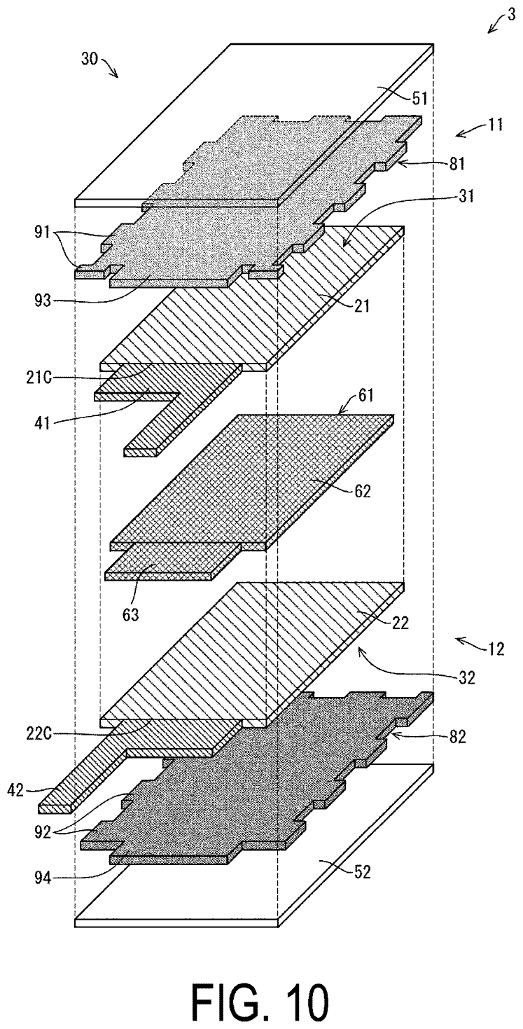

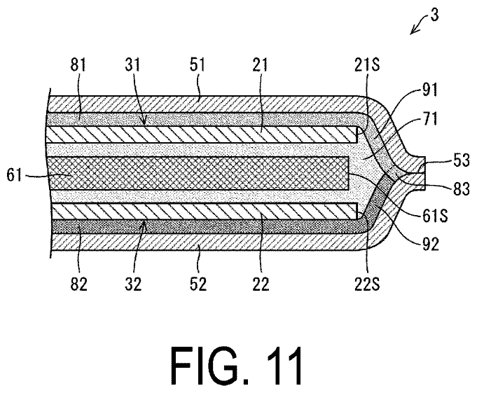

FIG. 9 is a schematic perspective view of a display device 3 according to this embodiment. FIG. 10 is a schematic exploded view of the display device 3 according to this embodiment. FIG. 11 is a schematic side cross-sectional view of a portion of the display device 3 according to this embodiment. In particular, FIG. 11 is a cross-sectional view taken along a line A-A in FIG. 9, in other words, illustrates a side cross-section substantially parallel to the layering direction of a display unit 30 in the vicinity of an end edge of the display unit 30 of the display device 3 in a plan view. However, in order to describe the configuration of the display device 3 according to this embodiment in more detail, FIG. 11 also illustrates a first protruding part 91, a second protruding part 92, and a bonding part 83 which is a part where the first protruding part 91 and the second protruding part 92 are bonded together, which will be described later, in the vicinity of the cross-section.

The display device 3 according to this embodiment differs in configuration from the display device 1 described above in that it includes the display unit 30 instead of the display unit 10. The display unit 30 according to this embodiment differs in configuration from the display unit 10 of the previous embodiment in that it further includes a first bonding plate 81 and a second bonding plate 82.

The first bonding plate 81 is positioned between a first display panel 21 and a first film 51. The second bonding plate 82 is positioned between a second display panel 22 and a second film 52. The first bonding plate 81 and the second bonding plate 82 include a light-transmitting bonding material such as OCA. For this reason, as illustrated in FIG. 11, the first display panel 21 and the first film 51 are bonded together via the first bonding plate 81, and the second display panel 22 and the second film 52 are bonded together via the second bonding plate 82.

### First Protruding Part and Second Protruding Part

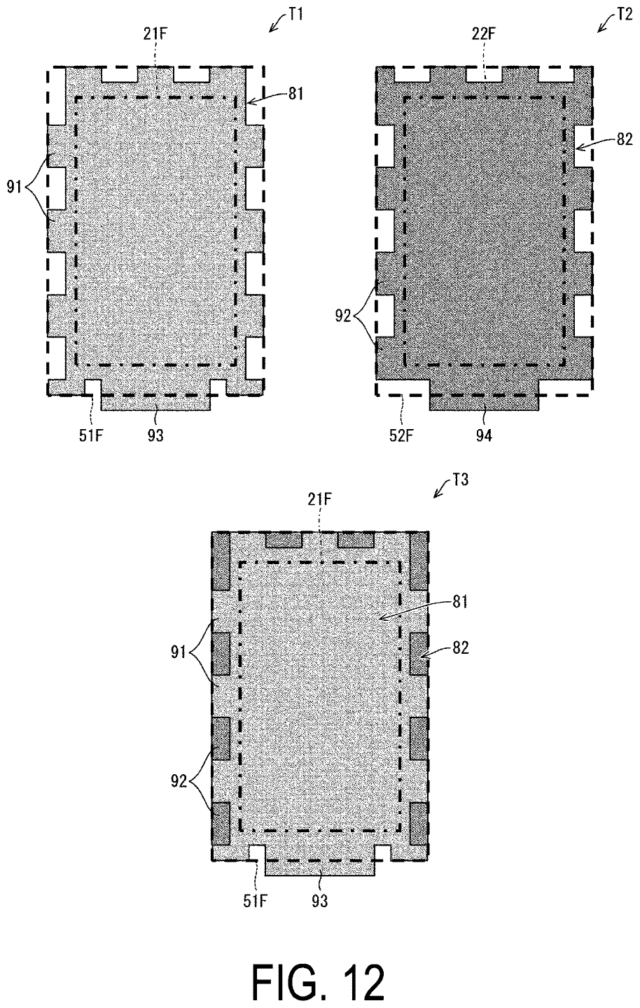

Specific shapes of the first bonding plate 81 and the second bonding plate 82 will be described in more detail with reference to FIG. 12. FIG. 12 is a schematic diagram of each bonding plate. In particular, a schematic diagram T1 of FIG. 12 illustrates the first bonding plate 81 in a plan view, and a schematic diagram T2 of FIG. 12 illustrates the second bonding plate 82 in a plan view. Furthermore, a schematic diagram T3 of FIG. 12 illustrates the first bonding plate 81 and the second bonding plate 82 extracted from the display unit 30 in a plan view.

In each schematic diagram of FIG. 12, an outer shape 51F of the first film 51 or an outer shape 52F of the second film 52 of the display unit 30 in a plan view is illustrated by a dotted line. In each schematic diagram of FIG. 12, an outer shape 21F of the first display panel 21 or an outer shape 22F of the second display panel 22 of the display unit 30 in a plan view is illustrated by a dashed line. In a plan view of the display unit 30, the outer shape 51F and the outer shape 52F substantially overlap each other, and the outer shape 21F and the outer shape 22F substantially overlap each other.

As illustrated in the schematic diagram T1, the first bonding plate 81 has a plurality of first protruding parts 91, and as illustrated in the schematic diagram T2, the second bonding plate 82 has a plurality of second protruding parts 92. In a plan view of the display unit 30, all of the first protruding parts 91 are positioned outside the outer shape 21F, and all of the second protruding parts 92 are positioned outside the outer shape 22F. Thus, since the outer shape 21F and the outer shape 22F substantially overlap each other in a plan view of the display unit 30, both of the first protruding parts 91 and the second protruding parts 92 protrude from the first display panel 21 and the second display panel 22 in a plan view.

Furthermore, as illustrated in the schematic diagram T3, the second protruding parts 92 do not overlap the first protruding parts 91 in a plan view, in other words, the second protruding parts 92 overlap the periphery of the first protruding parts 91 in a plan view. For example, in a plan view, some of the second protruding parts 92 may be positioned between the first protruding parts 91.

Furthermore, the first bonding plate 81 may overlap a first circuit board 41 and have a first circuit board protruding part 93 that protrudes around the first film 51 in a plan view. The second bonding plate 82 may overlap the second circuit board 42 and have a second circuit board protruding part 94 that protrudes around the second film 52 in a plan view.

### Bonding Between First Bonding Plate and Second Bonding Plate

The first bonding plate 81 and the second bonding plate 82 are bonded together in the display unit 30. In particular, the first bonding plate 81 and the second bonding plate 82 are bonded together at a bonding part 83, illustrated in FIG. 8, which is positioned around the first display panel 21 and the second display panel 22 in a plan view. The bonding part 83 is formed by bonding the first protruding part 91 and the second protruding part 92 together. In other words, the first bonding plate 81 and the second bonding plate 82 are bonded together by bonding at least a portion of the first protruding part 91 and at least a portion of the second protruding part 92 together.

In this embodiment, the first display panel 21 and the heat dissipation plate 61 may be bonded together, and the second display panel 22 and the heat dissipation plate 61 may be bonded together using a resin bonding material 71. However, this is not limiting, and the display unit 30 may include a heat dissipation bonding part 72 instead of the heat dissipation plate 61, and the first display panel 21 and the second display panel 22 may be bonded together via the heat dissipation bonding part 72.

Apart from the above description, the display device 3 according to this embodiment has the same configuration as the display device 1 or display device 2 described above. Thus, for the same reasons as those described above, the display device 3 improves the durability and reliability of the display unit 30 or improves the display quality of at least one of a first display surface 31 and a second display surface 32.

Furthermore, in the display device 3, when the display unit 30 is viewed in a plan view, not only the films are bonded around each display panel, but the first bonding plate 81 and the second bonding plate 82 are bonded together. For this reason, in the display device 3, the first bonding plate 81 and the second bonding plate 82 used for bonding of each display panel and each film can be given a function of reducing the penetration of foreign matter into each display panel. Furthermore, since the first bonding plate 81 and the second bonding plate 82 are positioned at the side of each display panel, the display device 3 increases the thickness of the side of the display unit 30, improving impact resistance at the side of the display unit 30. Thus, the display device 3 extends its life or improves impact resistance with a simpler configuration.

In particular, the first bonding plate 81 and the second bonding plate 82 are bonded together at the first protruding part 91 and the second protruding part 92. For this reason, the bonding part 83 is formed by the first protruding part 91 and the second protruding part 92 fitting between each other and by bonding of the respective side surfaces of the first protruding part 91 and the second protruding part 92. Thus, the display device 3 reduces the thickness of the bonding part 83 in the layering direction of the display unit 30. Thus, the display device 3 reduces the thickness at the side of the display unit 30 or improves the degree of freedom of design at the side of the display unit 30.

### Another Example of Method of Manufacturing Display Device

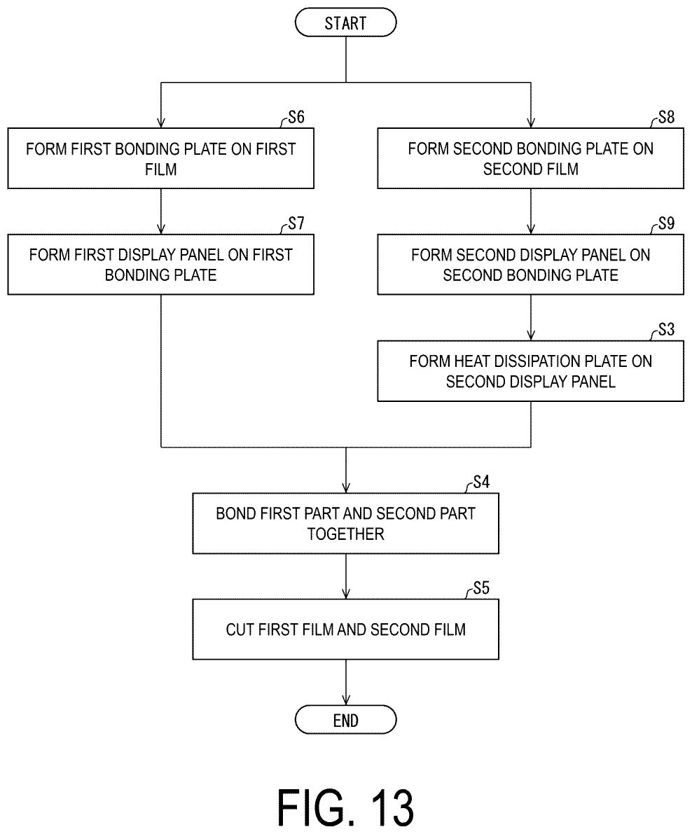

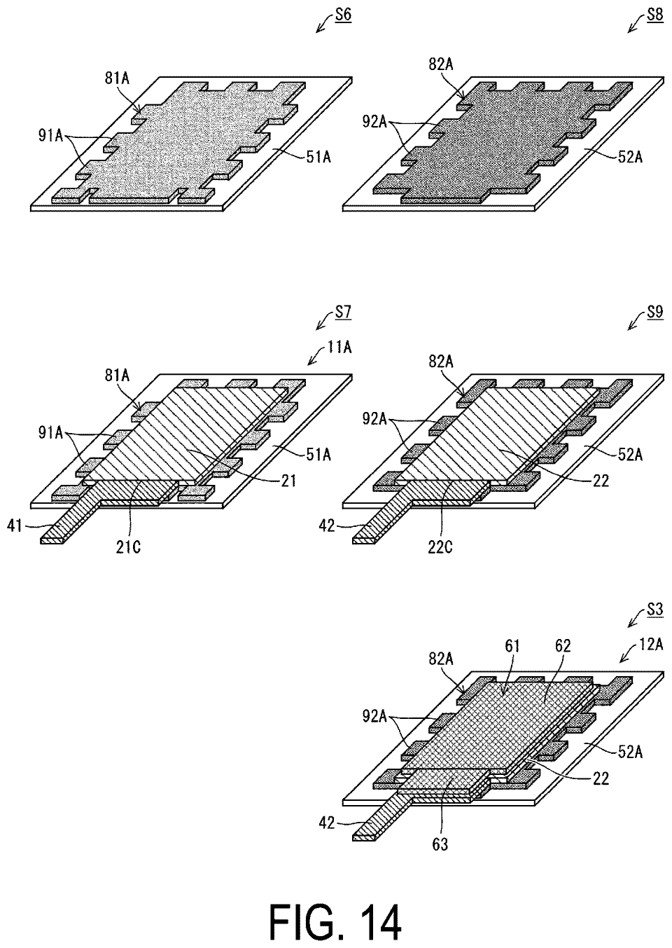

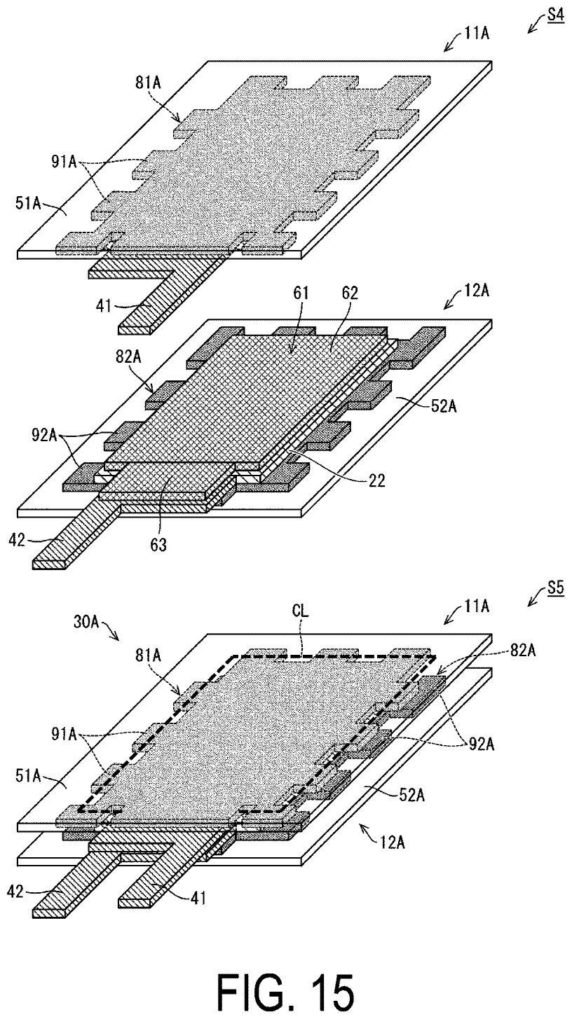

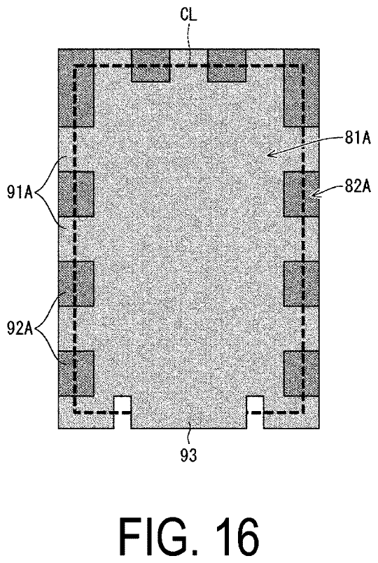

A method of manufacturing the display device 3 according to this embodiment will be described with reference to FIGS. 13 to 16. FIG. 13 is a flowchart of the method of manufacturing the display device 3 according to this embodiment. FIGS. 14 and 15 are perspective views illustrating steps of the method of manufacturing the display device 3 according to this embodiment. FIG. 16 is a schematic diagram illustrating cutting positions of a first bonding plate 81A and a second bonding plate 82A when cutting each film to be described later. In particular, FIG. 16 is a plan view illustrating the first bonding plate 81A and the second bonding plate 82A, which will be described later, extracted from a layered body 10A formed in the method of manufacturing the display device 3 according to this embodiment.

In the method of manufacturing the display device 3 according to this embodiment, first, the first bonding plate 81A is formed on a first film 51A (step S6). The first bonding plate 81A differs from the first bonding plate 81 only in that, instead of the first protruding part 91, the first bonding plate 81A has a first protruding part 91A that protrudes more toward the peripheral side in a plan view than the first protruding part 91. The first bonding plate 81A may be formed by forming an adhesive layer including OCA or the like on a first film 51A and then patterning the adhesive layer.

Next, the first display panel 21 is formed on the first bonding plate 81A (step S7). Step S7 may be performed in the same manner as step S1, except that a formation position of the first display panel 21 is changed from a position on the first film 51A to a position on the first bonding plate 81A. The first part 11A is formed in this manner.

Apart from the formation of the first part 11A, in the method of manufacturing the display device 3 according to this embodiment, a second bonding plate 82A is formed on a second film 52A (step S8). The second bonding plate 82A differs from the second bonding plate 82 only in that, instead of the second protruding part 92, the second bonding plate 82A has a second protruding part 92A that protrudes more toward the peripheral side in a plan view than the second protruding part 92. Step S8 may be realized by the same method as in step S6.

Next, the second display panel 22 is formed on the second bonding plate 82A (step S9). Step S9 may be executed by the same method as in step S2, except that a formation position of the second display panel 22 is changed from a position on the second film 52A to a position on the second bonding plate 82A.

Next, the heat dissipation plate 61 is formed on the second display panel 22 by the same method as in step S3 described above. The second part 12A is formed in this manner.

Subsequently to steps S7 and S3, the first part 11A and the second part 12A are bonded together by the same method as in step S4 described above. As described above, the layered body 10A is formed such that the second film 52A, the second bonding plate 82A, the second display panel 22, the heat dissipation plate 61, the first display panel 21, the first bonding plate 81A, and the first film 51 are layered in this order.

Next, the first film 51A and the second film 52A are cut by the same method as in step S5. The first film 51A and the second film 52A are cut, for example, by cutting a layered body 30A including the first film 51A and the second film 52A along a cutting line CL illustrated in FIG. 15 or FIG. 16.

In particular, as illustrated in FIG. 16, in a plan view of the layered body 30A, the cutting line CL is at a position overlapping each of the first protruding part 91A and the second protruding part 92A, except for the positions where it overlaps the first circuit board protruding part 93 and the second circuit board protruding part 94. For this reason, by cutting the first film 51A and the second film 52A, the first protruding part 91A and the second protruding part 92A are also cut together in step S5 of this embodiment. Thereby, the first protruding part 91A becomes the first protruding part 91, and the second protruding part 92A becomes the second protruding part 92. Thus, in step S5 of this embodiment, the first bonding plate 81 is formed from the first bonding plate 81A, and the second bonding plate 82 is formed from the second bonding plate 82A.

Also in step S5 of this embodiment, the cutting of the first film 51A and the second film 52A may be fusing of the first film 51A and the second film 52A using a laser beam or the like. In this case, in step S5, not only the bonding of the first film 51 and the second film 52 but also the bonding of the first protruding part 91 and the second protruding part 92 may be realized.

As described above, the layered body 30A becomes the display unit 30 including the first part 11 and the second part 12, and the display device 3 is manufactured. As described above, the display device 3 manufactured by the above-described method improves the durability and reliability of the display unit 30 or improves the display quality of at least one of the first display surface 31 and the second display surface 32.

### Supplement

A display device of a first aspect of the disclosure is a display device including a display unit having flexibility, in which the display unit includes a first film, a second film overlapping the first film in a plan view, a first display panel positioned between the first film and the second film and including a display surface on a side of the first film, a second display panel positioned between the second film and the first display panel and including a display surface on a side of the second film, and a heat dissipation part positioned between the first display panel and the second display panel and having a thermal conductivity higher than that of at least one of the first display panel and the second display panel, and the first film and the second film are bonded together around the first display panel and the second display panel in a plan view.

In a display device of a second aspect of the disclosure according to the first aspect, at least one of the first film and the second film may be a polarizing film.

In a display device of a third aspect of the disclosure according to the first or second aspect, at least one of the first film and the second film may include polyimide.

In a display device of a fourth aspect of the disclosure according to any one of the first to third aspects, the first display panel and the second display panel may be bonded together via the heat dissipation part.

In a display device of a fifth aspect of the disclosure according to any one of the first to fourth aspects, the heat dissipation part may include a flat heat dissipation plate positioned between the first display panel and the second display panel.

A display device of a sixth aspect of the disclosure according to any one of the first to fifth aspects may further include a first circuit board connected to a side of the first display panel, and a second circuit board connected to a side of the second display panel.

In a display device of a seventh aspect of the disclosure according to the sixth aspect, each of the first display panel and the second display panel may have a rectangular shape having four sides in a plan view, the first circuit board may be connected to a side of a first side which is one of the four sides of the first display panel, and the second circuit board may be connected to a side of a second side which is one of the four sides of the second display panel and is positioned on the same side as the first side in a plan view, and the first film and the second film may be connected to each other around all of the sides different from the first side and the second side in a plan view among the four sides of the first display panel and the second display panel.

In a display device of an eighth aspect of the disclosure according to the sixth or seventh aspect, at least a portion of the first circuit board and at least a portion of the second circuit board may overlap each other in a plan view, and a portion of the heat dissipation part may overlap both the first circuit board and the second circuit board in a plan view.

In a display device of a ninth aspect of the disclosure according to any one of the first to eighth aspect, the display unit may include a first bonding plate positioned between the first film and the first display panel, and a second bonding plate positioned between the second film and the second display panel, the first film and the first display panel may be bonded together via the first bonding plate, and the second film and the second display panel may be bonded together via the second bonding plate, and the first bonding plate and the second bonding plate may be bonded together around the first display panel and the second display panel in a plan view.

In a display device of a tenth aspect of the disclosure according to the ninth aspect, the first bonding plate may have a first protruding part that protrudes from the first display panel and the second display panel in a plan view, the second bonding plate may have a second protruding part that protrudes from the first display panel and the second display panel in a plan view and overlaps a periphery of the first protruding part in a plan view, and at least a portion of the first protruding part and at least a portion of the second protruding part may be bonded together.

In a display device of an eleventh aspect according to any one of the first to tenth aspects of the disclosure, the display unit may include a resin bonding material filled between a bonding part between the first film and the second film and sides of the first display panel, the second display panel, and the heat dissipation part.

In a display device of a twelfth aspect of the disclosure according to the eleventh aspect, the resin bonding material may be a bonding material having light-transmitting property.

In a display device of a thirteenth aspect of the disclosure according to any one of the first to twelfth aspects, at least one of the first display panel and the second display panel may be an organic EL light-emitting panel including an organic EL element, or a quantum dot light-emitting panel including a quantum dot light-emitting element.

A method of manufacturing a display device of a fourteenth aspect of the disclosure is a method of manufacturing a display device including a display unit having flexibility, the method including forming the display unit, in which formation of the display unit includes forming a layered body including a first film, a second film overlapping the first film in a plan view, a first display panel positioned between the first film and the second film and including a display surface on a side of the first film, a second display panel positioned between the second film and the first display panel and including a display surface on a side of the second film, and a heat dissipation part positioned between the first display panel and the second display panel and having a thermal conductivity higher than that of at least one of the first display panel and the second display panel, and bonding the first film and the second film together around the first display panel and the second display panel in a plan view.

In a method of manufacturing a display device of a fifteenth aspect of the disclosure according to the fourteenth aspect, the bonding of the first film and the second film may include cutting the first film and the second film.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a display unit having flexibility,
wherein the display unit includes
a first film,
a second film overlapping the first film in a plan view,
a first display panel positioned between the first film and the second film and including a display surface on a side of the first film,
a second display panel positioned between the second film and the first display panel and including a display surface on a side of the second film, and
a heat dissipation part positioned between the first display panel and the second display panel and having a thermal conductivity higher than a thermal conductivity of at least one of the first display panel and the second display panel, and
the first film and the second film are bonded together around the first display panel and the second display panel in a plan view.

2. The display device according to claim 1,
wherein at least one of the first film and the second film is a polarizing film.

3. The display device according to claim 1,
wherein at least one of the first film and the second film includes polyimide.

4. The display device according to claim 1,
wherein the first display panel and the second display panel are bonded together via the heat dissipation part.

5. The display device according to claim 1,
wherein the heat dissipation part includes a flat heat dissipation plate positioned between the first display panel and the second display panel.

6. The display device according to claim 1, further comprising:
a first circuit board connected to a side of the first display panel; and
a second circuit board connected to a side of the second display panel.

7. The display device according to claim 6,
wherein each of the first display panel and the second display panel has a rectangular shape having four sides in a plan view,
the first circuit board is connected to a side of a first side which is one of the four sides of the first display panel, and the second circuit board is connected to a side of a second side which is one of the four sides of the second display panel and is positioned on the same side as the first side in a plan view, and
the first film and the second film are connected to each other around all of the sides different from the first side and the second side in a plan view among the four sides of the first display panel and the second display panel.

8. The display device according to claim 6,
wherein at least a portion of the first circuit board and at least a portion of the second circuit board overlap each other in a plan view, and
a portion of the heat dissipation part overlaps both the first circuit board and the second circuit board in a plan view.

9. The display device according to claim 1,
wherein the display unit includes a first bonding plate positioned between the first film and the first display panel, and a second bonding plate positioned between the second film and the second display panel,
the first film and the first display panel are bonded together via the first bonding plate, and the second film and the second display panel are bonded together via the second bonding plate, and
the first bonding plate and the second bonding plate are bonded together around the first display panel and the second display panel in a plan view.

10. The display device according to claim 9,
wherein the first bonding plate includes a first protruding part that protrudes from the first display panel and the second display panel in a plan view,
the second bonding plate includes a second protruding part that protrudes from the first display panel and the second display panel in a plan view and overlaps a periphery of the first protruding part in a plan view, and
at least a portion of the first protruding part and at least a portion of the second protruding part are bonded together.

11. The display device according to claim 1,
wherein the display unit includes a resin bonding material filled between
a bonding part between the first film and the second film and
sides of the first display panel, the second display panel, and the heat dissipation part.

12. The display device according to claim 11,
wherein the resin bonding material is a bonding material having light-transmitting property.

13. The display device according to claim 1,
wherein at least one of the first display panel and the second display panel is an organic EL light-emitting panel including an organic EL element, or a quantum dot light-emitting panel including a quantum dot light-emitting element.

14. A method of manufacturing a display device including a display unit having flexibility, the method comprising:
forming the display unit,
wherein the forming of the display unit includes
forming a layered body including a first film, a second film overlapping the first film in a plan view, a first display panel positioned between the first film and the second film and including a display surface on a side of the first film, a second display panel positioned between the second film and the first display panel and including a display surface on a side of the second film, and a heat dissipation part positioned between the first display panel and the second display panel and having a thermal conductivity higher than a thermal conductivity of at least one of the first display panel and the second display panel, and
bonding the first film and the second film together around the first display panel and the second display panel in a plan view.

15. The method of manufacturing the display device according to claim 14,
wherein the bonding of the first film and the second film includes cutting the first film and the second film.
